(19) United States
(12) Patent Application Publication
(10) Pub. No.: US 2025/0192066 A1
(43) Pub. Date: Jun. 12, 2025

(54) SEMICONDUCTOR WAFER WITH RECESSED PORTIONS AT A SCRIBE AREA

(71) Applicant: Micron Technology, Inc., Boise, ID (US)

(72) Inventors: Wei Zhou, Boise, ID (US); Kunal R. Parekh, Boise, ID (US); Kyle K. Kirby, Eagle, ID (US)

(21) Appl. No.: 18/951,382

(22) Filed: Nov. 18, 2024

Related U.S. Application Data
(60) Provisional application No. 63/607,231, filed on Dec. 7, 2023.

(51) Int. Cl. H01L 23/544; H01L 21/304; H01L 23/00; H01L 23/31; H01L 25/18; H10B 80/00

(52) U.S. Cl. CPC H01L 23/544; H01L 21/3043; H01L 23/3171; H01L 24/08; H01L 24/94; H01L 25/18; H01L 2223/5446; H01L 2224/08147; H01L 2224/94; H01L 2225/06513; H01L 2924/1431; H10B 80/00

(57) ABSTRACT

A semiconductor device assembly is disclosed. The semiconductor device assembly includes a semiconductor substrate on which a plurality of semiconductor dies are implemented. The semiconductor substrate includes a scribe area between the plurality of semiconductor dies. A layer of passivation material is disposed at a first side of the semiconductor substrate such that the layer of passivation material has one or more recessed portions at the scribe area.

### CROSS-REFERENCE TO RELATED APPLICATION(S)

The present application claims priority to U.S. Provisional Patent Application No. 63/607,231, filed Dec. 7, 2023, the disclosure of which is incorporated herein by reference in its entirety.

### TECHNICAL FIELD

The present disclosure generally relates to semiconductor device assembly and more particularly relates to a semiconductor wafer with recessed portions at a scribe area.

### BACKGROUND

Wafer bonding is a wafer-level packaging technology that can be used to form semiconductor device assemblies. During wafer bonding, the two semiconductor wafers can be brought into contact with one another at their respective bonding surfaces. The bonding surfaces can include conductive pads coupled with circuitry at each of the respective wafers and dielectric material surrounding the conductive pads. Once contacting, the conductive pads on each of the two semiconductor wafers can bond to form interconnects between the wafers. Similarly, the dielectric material at each respective wafers can bond to mechanically couple the two semiconductor wafers. During bonding, contaminants can be trapped at the bond line between two wafers and create voids. These voids can reduce the bond strength between the two semiconductor die or, in some cases, disconnect interconnects between the wafers, which can render the semiconductor devices implemented thereon inoperable.

### BRIEF DESCRIPTION OF THE DRAWINGS

FIG. 1 illustrates a simplified schematic cross-sectional view of a semiconductor device assembly that includes bonded semiconductor wafers implemented in accordance with an embodiment of the present technology.

FIG. 2A illustrates a simplified schematic partial plan view of a semiconductor wafer in accordance with an embodiment of the present technology.

FIG. 2B illustrates a simplified schematic partial plan view of a semiconductor wafer in accordance with an embodiment of the present technology.

FIGS. 3-6 illustrate simplified schematic cross-sectional views of a series of operations for assembling a semiconductor device in accordance with an embodiment of the present technology.

FIG. 7 illustrates a schematic view of a system that includes a semiconductor device in accordance with an embodiment of the present technology.

FIG. 8 illustrates a method for assembling a semiconductor device in accordance with an embodiment of the present technology.

### DETAILED DESCRIPTION

Semiconductor devices are integrated in many devices to implement memory cells, processor circuits, imager devices, and other functional features. As more applications for semiconductor devices are discovered, designers are tasked with creating improved devices that can perform a greater number of operations per second, store greater amounts of data, or operate with a higher level of security. Improvements in packaging have enabled multiple semiconductor dies to be assembled into a single package to implement a single packaged device with increased functionality. To implement this improved device with limited increase to the package footprint, semiconductor dies can be stacked onto one another.

Often, to form stacked semiconductor devices, two semiconductor wafers, each implementing multiple dies, can be bonded such that the respective dies on each of the wafers couple with one another. The bonding process can include forming interconnects between contacts at the respective semiconductor dies on each wafer and bonding passivation layers (e.g., of dielectric material) at respective bonding surfaces of the wafers. Generally, the bonding process must be controlled to ensure that the wafers are free of contaminants that, when present on the bonding surfaces, can create voids (e.g., portions of the bonding surfaces of the wafers that are unbonded). If the voids are large enough, they can weaken the bond between the semiconductor wafers to the point of failure or separate and short interconnects between bonded semiconductor dies, rendering these dies inoperable.

Limiting contamination at the bonding surface can be very difficult, in part because various steps of the bonding process can create contaminants. For example, the bonding process can include hydrating the bonding surfaces of the semiconductor wafers and contacting the wafers in a high-temperature or high-pressure environment. The wafers can bond along a bond wave that propagates from the center of the wafers to the edges. As the bond wave propagates, moisture can be pushed toward the edges of the wafers where there is a drop in pressure. As a result, the moisture can condense at the edges of the wafers, and this condensation can create voids along the bonding interface.

Moreover, contaminants can be created as a result of fusion bonding the semiconductor wafers. In some cases, the fusion bond between the passivation layers of the wafers can produce moisture that can accumulate at the bonding surfaces. As a specific example, fusion bonding between Si—OH at the passivation layers of the wafers can produce moisture at the bonding surfaces. If the moisture cannot be diffused through the passivation layer, it can form voids between wafers. Annealing the wafers at high temperatures can further cause dielectric films and other materials at the passivation layers to outgas and release contaminants at the bonding surfaces, which can be trapped between the wafers and create voids. Accordingly, additional solutions are needed to prevent the occurrence of voids during wafer bonding and improve production yield.

To address these problems and others, the embodiments of the present technology provide a semiconductor wafer having a passivation layer with one or more recessed portions at a scribe area between dies implemented on the semiconductor wafer. Contaminants present during or created as a result of the bonding process can be captured within the recessed portions such that the contaminants are removed from the bonding surfaces of the wafers. In doing so, the formation of voids between the wafers can be limited, thereby improving production yield. Given that the recessed portions are located within scribe areas between the semiconductor dies, the recessed portions, and the contaminants captured within, can be removed from the individual semiconductor devices during singulation. Thus, the recessed portions can be used to improve production yield during the assembly process without appearing in the final semiconductor device.

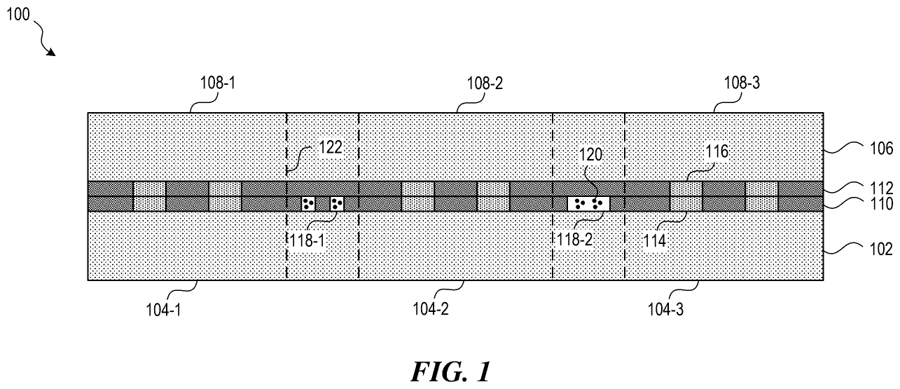

FIG. 1 illustrates a simplified schematic cross-sectional view of a semiconductor device assembly 100 that includes bonded semiconductor wafers implemented in accordance with an embodiment of the present technology. As illustrated, a semiconductor wafer 102 implements semiconductor die 104-1, semiconductor die 104-2, and semiconductor die 104-3 (referred to generally as semiconductor dies 104). Similarly, the semiconductor wafer 106 implements semiconductor die 108-1, semiconductor die 108-2, and semiconductor die 108-3 (referred to generally as semiconductor dies 108). The semiconductor wafer 102 and the semiconductor wafer 106 are bonded such that respective ones of the semiconductor dies 104 couple with corresponding ones of the semiconductor dies 108 (e.g., semiconductor die 104-1 couples with semiconductor die 108-1 and so on).

A passivation layer 110 and a passivation layer 112 are disposed at the semiconductor wafer 102 and the semiconductor wafer 106, respectively. The semiconductor wafer 102 and the semiconductor wafer 106 can be bonded at the passivation layer 110 and the passivation layer 112. For example, the passivation layer 110 and the passivation layer 112 can be directly bonded through fusion or hybrid bonding. The passivation layer 110 and the passivation layer 112 can include any number of insulating material. As a specific example, the passivation layer 110 or the passivation layer 112 can include a dielectric material, such as silicon oxide, silicon nitride, silicon carbide, silicon carbon nitride, and so on, or a polymer.

Contact pads 114 and contact pads 116 can be disposed within the passivation layer 110 and the passivation layer 112, respectively. The contact pads 114 can couple through connective circuitry (e.g., traces, lines, vias) to functional circuitry (e.g., transistors, diodes, gates) at the semiconductor dies 104. Similarly, the contact pads 116 can couple through connective circuitry to functional circuitry at the semiconductor wafers 106. The contact pads 114 and the contact pads 116 can be disposed at corresponding locations such that respective ones of the contact pads 114 couple with corresponding ones of the contact pads 116 when the semiconductor wafer 102 and the semiconductor wafer 106 are coupled. The contact pads 114 and the contact pads 116 can form interconnects (e.g., metal-metal interconnects) between the semiconductor dies 104 and the semiconductor dies 108.

As illustrated, the passivation layer 110 includes recessed portions 118-1 and recessed portion 118-2 (referred to collectively as recessed portions 118). The recessed portions 118 can be recessed from a bonding surface of the passivation layer 110. In this way, the semiconductor wafer 106 can cover the recessed portions 118-2 to form a channel at which contaminants 120 can be trapped. The recessed portions 118 can be implemented within scribe areas between the semiconductor dies 104. The scribe areas can be defined by scribe lines 122 between the semiconductor dies 104 at which the semiconductor wafer 102 is to be sawed to singulate the semiconductor dies 104. In general, the scribe area is void of functional circuitry as it will be sawed through during assembly. Instead, the functional circuitry of the semiconductor dies 104 can be implemented outside of the scribe area. Additionally or alternatively the recessed portions 118 can be implemented in the passivation layer 110 within a lateral area where the semiconductor dies 104 are implemented (e.g., above functional circuitry of the semiconductor dies 104 and spaced from the contact pads 114.

The recessed portions 118 can be implemented in any number of shapes. For example, although illustrated with a rectangular cross section, the recessed portions 118 could instead be implemented with a “v” shape, diamond, rounded, or any other cross section. The recessed portions 118-1 include a plurality of discrete recessed portions between the semiconductor die 104-1 and the semiconductor die 104-2. In contrast, the recessed portion 118-2 includes only a single recessed portion between the semiconductor die 104-2 and the semiconductor die 104-3. In general, however, the recessed portions 118 can capture contaminants 120 present during or resulting from the bonding process to prevent these contaminants from causing voids between the semiconductor wafer 102 and the semiconductor wafer 106. In some cases, the recessed portions 118 can be sized to hold a particular amount of contaminants. For example, the recessed portions 118 can have a volume greater than or equal to the amount of contaminants 120 moved, formed, or released during the bonding process. Similarly, the recessed portions 118 can have a width that is less than the respective widths of respective scribe areas in which each respective one of the recessed portions 118 are implemented to enable the recessed portions 118 to be implemented fully within the scribe area. As a specific example, the recessed portions 118 can have a width of less than 10, 20, 30, 50, or any other number of microns. Further the depth of the recessed portions 118 can be less than the thickness of the passivation layer 110. As a specific example, the recessed portions 118 can have a depth less than 10, 20, 30, 50, 100, 1000, or any other number of nanometers.

Although not illustrated, the semiconductor wafer 106 can similarly include one or more recessed portions implemented within the passivation layer 112. The recessed portions implemented within the passivation layer 112 can correspond to the recessed portions 118 such that when the semiconductor wafer 102 and the semiconductor wafer 106 are bonded, the recessed portions form larger channels implemented within the passivation layer 110 and the passivation layer 112. Alternatively or additionally, the recessed portions within the passivation layer 112 can be implemented at different locations than the recessed portions 118 such that discrete channels are formed in the passivation layer 110 and the passivation layer 112.

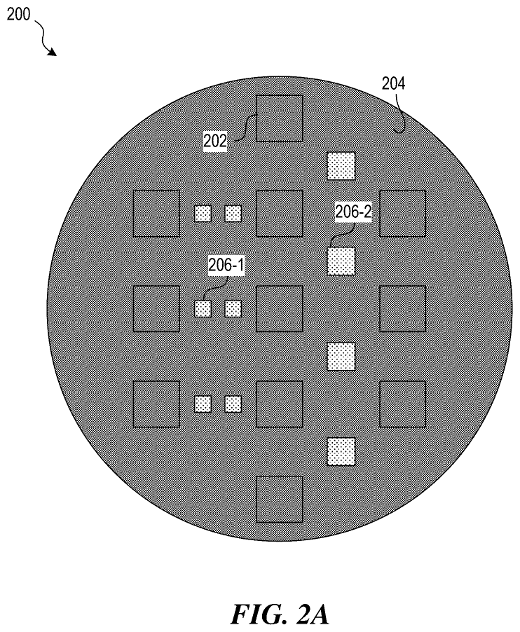

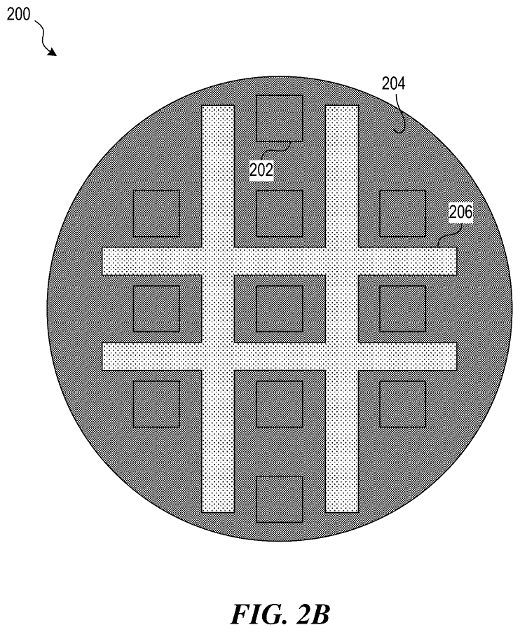

FIG. 2A illustrates a simplified schematic partial plan view of a semiconductor wafer 200 (e.g., an example of the semiconductor wafer 102 illustrated in FIG. 1) in accordance with an embodiment of the present technology. The semiconductor wafer 200 includes semiconductor dies 202 implemented at different lateral locations of the semiconductor wafer 200. The semiconductor dies 202 can be spaced from one another to enable the semiconductor dies 202 to be singulated from one another through sawing at scribe areas between them. A passivation layer 204 (e.g., an example of the passivation layer 110 illustrated in FIG. 1) is disposed at the semiconductor wafer 200. The passivation layer 204 includes one or more recessed portions (e.g., recessed portions 206-1 and recessed portions 206-2, referred to generally as recessed portions 206). The recessed portions 206 can be used to capture contaminants at the bonding surface (e.g., the surface illustrated in FIG. 2A) before they affect the bonding process.

The recessed portions 206 can be implemented at any location within the scribe area between the semiconductor dies 202. Similarly, the recessed portions 206 can be implemented in any shape. As illustrated, the recessed portions 206 are implemented as holes that do not span large lateral distances across the semiconductor wafer 200. Instead, the recessed portions 206 extend within a single location similar to a via hole. The recessed portions 206 can be implemented in any shape. For example, as illustrated, the recessed portions 206 have a rectangular (e.g., square) cross section. In other implementations, one or more of the recessed portions 206 can have a cross section of a different shape, such as a polygonal (e.g., trapezoidal, rhomboidal, triangular, pentagonal, hexagonal, and so on), round, or freeform shape. The recessed portions 206 can have a common size or be of varying sizes.

Different possible implementations of the recessed portions 206-1 are illustrated in FIG. 2A. For example, the recessed portions 206-1 include multiple discrete recessed portions implemented between each pair of the semiconductor dies 202. The discrete portions are disconnected and separated from one another by the passivation layer 204. The recessed portions 206-1 are entirely within the scribe area directly between each pair of semiconductor dies 202. Alternatively or additionally, the recessed portions 206-1 can be at least partially outside the area directly between the semiconductor dies 202 while still within a scribe area of the semiconductor wafer 200. In contrast to the recessed portions 206-1, the recessed portions 206-2 include only a single recessed portion for each pair of semiconductor dies 202. The recessed portions 206-2 are also staggered from the semiconductor dies 202 such that at least some of the recessed portions 206-2 are implemented within the scribe area at a portion that is not directly between the semiconductor dies 202.

Although specific examples are provided, it should be appreciated that the recessed portions 206 could be implemented in any number of other ways or at different locations. For example, the recessed portions 206 need not be implemented between each pair of semiconductor dies 202. Moreover, the recessed portions 206 can be implemented at locations that are not directly between multiple semiconductor dies 202. For instance, the recessed portions 206 can be implemented at a scribe area between the edge of the semiconductor wafer 200 and the semiconductor dies 202 closest to the edge of the semiconductor wafer 200. In yet another aspect, the one or more of the recessed portions 206 can be implemented as trenches that extend laterally across large portions of the semiconductor wafer 200, as illustrated in FIG. 2B.

FIG. 2B illustrates a simplified schematic partial plan view of the semiconductor wafer 200 in accordance with an additional embodiment of the present technology. As illustrated, the recessed portions 206 in the passivation layer 204 are implemented within a scribe area between the semiconductor dies and extend laterally across the semiconductor wafer 200. For example, two parallel trenches extend between respective sets of multiple pairs of semiconductor dies. These trenches have a major axis that extends vertically (as illustrated in FIG. 2B) between columns of the semiconductor dies 202. The recessed portions 206 further include two additional trenches that are substantially perpendicular (e.g., within 10 degrees, 5 degrees, or 1 degree) to the two parallel trenches discussed above. The two additional trenches have a major axis that extends horizontally (as illustrated in FIG. 2B) between rows of the semiconductor dies 202. As illustrated, the trenches form a continuous recessed portion, however, in other cases, the recessed portions 206 can include discrete trenches separated by the passivation layer 204. Moreover, like discussed with respect to FIG. 2A, the recessed portions 206 can include multiple trenches between a single pair of columns or rows of the semiconductor dies 202 or trenches within a scribe area between the edge of the semiconductor wafer 200 and semiconductor dies 202 closest to the edge of the semiconductor wafer 200.

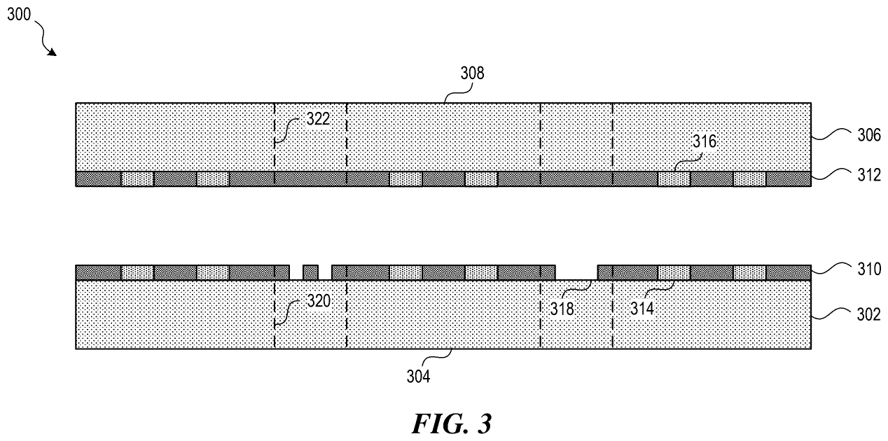

This disclosure now turns to a series of steps for fabricating semiconductor device assemblies in accordance with embodiments of the present technology. Specifically, FIGS. 3-6 illustrate simplified schematic cross-sectional views of a series of operations for assembling a semiconductor device in accordance with embodiments of the present technology. The operations are illustrated with respect to specific embodiments for ease of description. However, the operations described with respect to FIGS. 3-6 could be performed to fabricate semiconductor device assemblies in accordance with other embodiments.

Beginning with FIG. 3 at stage 300, semiconductor wafer 302 (e.g., an example of the semiconductor wafer 102 illustrated in FIG. 1), including semiconductor dies 304, and a semiconductor wafer 306, including semiconductor dies 308 are provided. A passivation layer 310 is disposed at a first side of the semiconductor wafer 302 through any number of techniques, such as chemical vapor deposition (CVD), physical vapor deposition (PVD), dispensing, oxidation, spin coating, and/or other suitable techniques. The passivation layer 310 can include a passivation material, such as dielectric material, a polymer, or another insulative material. The passivation layer 310 can provide insulation to the semiconductor dies 304 and create a bonding surface at which additional semiconductor dies can be attached. Contact pads 314 coupled with circuitry at the semiconductor dies 304 can be disposed at the first side of the semiconductor wafer 302 and at least partially surrounded by the passivation layer 310. The contact pads 314 can be exposed at the bonding surface to provide electrical connectivity between the semiconductor dies 304 and additional semiconductor dies attached at the bonding surface.

The passivation layer 310 can have recessed portions 318 located within scribe areas (defined by scribe lines 320) of the semiconductor wafer 302. The scribe area can be located outside of the footprint of the semiconductor dies 304 (e.g., between the semiconductor dies 304). The recessed portions 318 can be implemented by recessing one or more portions of the passivation layer 310 from the bonding surface. The recessed portions 318 can be formed into any shape or implemented at any location within the scribe areas, as discussed above. In some cases, the recessed portions 318 can be implemented through processes of depositing and removing passivation material. For example, in some cases, the recessed portions 318 can be formed by disposing the passivation layer 310 in a continuous layer absent recessed portions, and passivation material can be removed at portions of the passivation at which the recessed portions 318 are to be implemented. The passivation material can be removed through any number of techniques, such as using plasma etching, wet etching, drilling, or other suitable techniques. In yet other aspects, the passivation layer 310 can be selectively deposited (e.g., through masks or other selective deposition techniques) such that the passivation layer 310 includes the recessed portions 318.

The semiconductor wafer 306 can similarly be provided. For example, the passivation layer 312 can be disposed at a second side of the semiconductor wafer 306 to implement a bonding surface at which additional semiconductor dies can couple with the semiconductor dies 308. Contact pads 316 coupled with circuitry at the semiconductor dies 308 can be exposed at the bonding surface at least partially within the passivation layer 312. The contact pads 316 can be used to implement interconnects that are electrically connected with the semiconductor dies 308. Although not illustrated in FIG. 3, in some cases, the passivation layer 312 can include recessed portions similar to the recessed portions 318. The recessed portions within the passivation layer 312 can be disposed at locations that laterally correspond to the recessed portions 318 or at lateral locations that are different from the lateral locations at which the recessed portions 318 are implemented. The recessed portions of the passivation layer 312 can be located within scribe areas (defined by scribe lines 322) that correspond to the scribe areas of the semiconductor wafer 302.

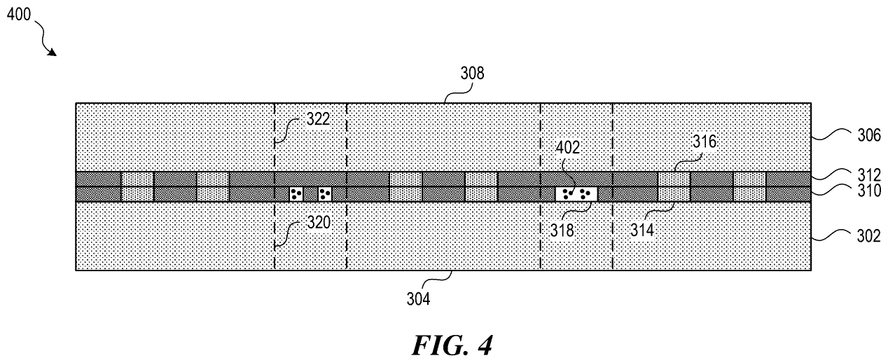

Turning next to FIG. 4 at stage 400, the semiconductor wafer 302 and the semiconductor wafer 306 are bonded such that the semiconductor dies 304 couple with the semiconductor dies 308. Bonding the semiconductor wafer 302 and the semiconductor wafer 306 can be performed through any number of bonding techniques, such as fusion or hybrid bonding. The bonding can form bonds (e.g., direct bonds, fusion bonds, hybrid bonds) between the passivation layer 310 and the passivation layer 312 and bonds (e.g., metal-metal bonds) between the contact pads 314 and the contact pads 316. During bonding, the bonding surfaces of the semiconductor wafer 302 and the semiconductor wafer 306 can be hydrated. As a result, moisture can be present at the passivation layer 310 and the passivation layer 312. The bonding can be initiated from the center of the semiconductor wafer 302 and the semiconductor wafer 306, and a bond wave can propagate toward the edges of the wafers to create the bond. As the bond wave propagates through the wafers, moisture can be pushed toward the edges of the wafers. In other bonding processes, as the moisture reaches the edges of the wafers, a drop in pressure can cause the moisture to condense at the bonding interface, which can result in voids. In contrast to these techniques, moisture pushed along the bonding wave can be collected in the recessed portions 318, where it is trapped harmlessly away from the bonding interface.

Once the initial bond is complete, the wafers can be annealed in a high-temperature or high-pressure environment to strengthen the bonds between the passivation layer 310 and the passivation layer 312 and cause the contact pads 314 and the contact pads 316 to diffuse to form an interconnect. As the passivation layer 310 and the passivation layer 312 bond, the reaction can form moisture, which, in other bonding techniques, can accumulate at the bonding interface and separate the wafers. To prevent such a separation, the moisture can be collected within the recessed portions 318 and kept clear of the bonding surfaces of the wafers.

In yet other aspects, annealing the wafers can cause the passivation layer 310, the passivation layer 312, or other portions of the semiconductor wafer 302 or the semiconductor wafer 306 to outgas contaminants into the bonding interface. For example, dielectric films utilized to implement the passivation layer 310 or the passivation layer 312 can include gasses that are released at high temperatures. In other bonding techniques, these outgasses can create voids at the bonding interface. By implementing recessed portions 318 within the passivation layer 310 (or the passivation layer 312), however, the outgasses can be accumulated within the recessed portions 318 without contaminating the bonding interface. As a result, contaminants 402 (e.g., moisture, outgasses, and other substances) can be trapped within the recessed portions 318.

Once bonded, the semiconductor wafer 302 and the semiconductor wafer 306 can be attached such that respective ones of the semiconductor dies 304 couple with corresponding ones of the semiconductor dies 308. The contact pads 314 and the contact pads 316 can form interconnects electrically coupling the semiconductor dies 304 and the semiconductor dies 308. In some cases, the bonding interface between the semiconductor wafer 302 and the semiconductor wafer 306 can be absent or present fewer voids due to the contaminants 402 being trapped within the recessed portions 318. This reduction in voids can result in a stronger bond between the wafers and more robustly bonded interconnects that are not separated and shorted, thereby improving the overall yield of the bonding process. Moreover, given that the recessed portions 318 are implemented within the scribe areas (defined by the scribe lines 320 and the scribe lines 322), bonding between the semiconductor dies 304 and the semiconductor dies 308 can be largely unaffected by the recessed portions 318.

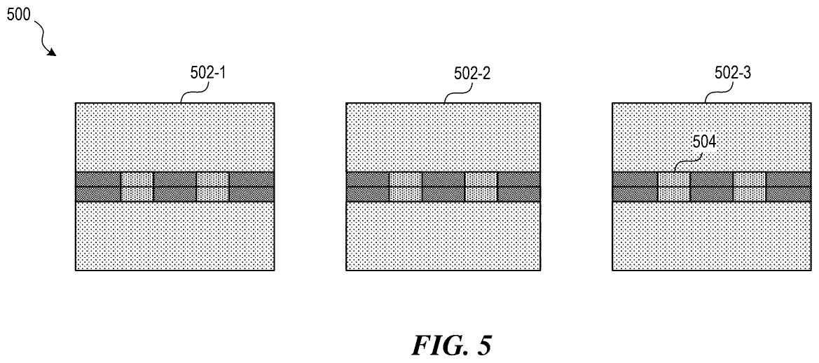

Once bonded, the semiconductor wafer 302 and the semiconductor wafer 306 can be sawed at the scribe areas to singulate the semiconductor dies 304 and the semiconductor dies 308. In some cases, the semiconductor wafer 302 and the semiconductor wafer 306 can be sawed at multiple locations within the scribe area on opposite sides of the recessed portions 318. For example, the semiconductor wafer 302 and the semiconductor wafer 306 can be sawed between the recessed portions 318 and the middle ones of the semiconductor dies 304 and the semiconductor dies 308 (as illustrated in FIG. 4) and sawed between the recessed portions 318 and the rightmost ones of the semiconductor dies 304 and the semiconductor dies 308. As a result, the recessed portions 318, and the contaminants 402 contained therein, can be removed from the semiconductor device assembly. The resultant stacks of semiconductor dies are illustrated in FIG. 5.

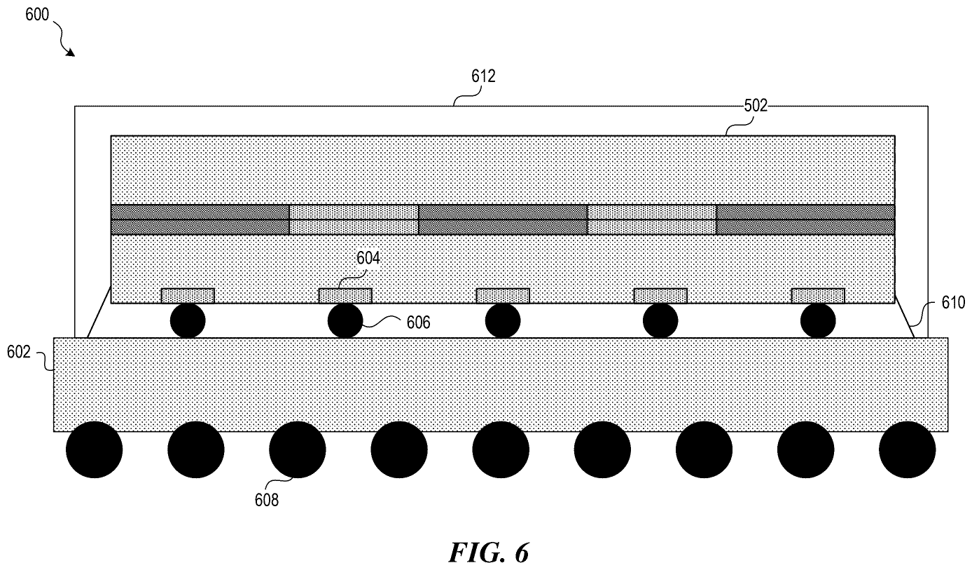

Turning next to FIG. 5 at stage 500, multiple stacks of semiconductor dies (stack of semiconductor dies 502-1, stack of semiconductor dies 502-2, and stack of semiconductor dies 502-3, referred to generally as stacks of semiconductor dies 502) are singulated. The singulated stacks of semiconductor dies 502 can include pairs of semiconductor dies electrically and mechanically coupled through interconnects 504 (e.g., metal-metal interconnects formed from the contact pads). The stacks of semiconductor dies can then be packaged into a semiconductor device, as illustrated in FIG. 6.

Turning to FIG. 6 at stage 600, a stack of semiconductor dies 502 is illustrated within a package. The stack of semiconductor dies 502 is attached to a package-level substrate 602 (e.g., printed circuit board (PCB), interposer, semiconductor substrate, another semiconductor die). The stack of semiconductor dies 502 includes one or more external contact pads 604 (e.g., disposed before or after sawing the semiconductor wafers) coupled through connective circuitry (e.g., traces, lines, vias, and so on) to circuitry at the stack of semiconductor dies 502. Interconnects 606 (e.g., solder, conductive pillars, or the like) can be formed between the contact pads 604 and contacts (not shown) at the package-level substrate 602 to enable electrical signals to pass between the stack of semiconductor dies 502 and the package-level substrate 602. The package-level substrate 602 can further include package-level contact pads (not shown) that provide external connectivity (e.g., power, ground, and input/output (I/O) signals) through solder balls 608 or other connective structures to the stack of semiconductor dies 502. Traces, lines, vias, and other electrical connection structures in the package-level substrate 602 can electrically connect the package-level contact pads to contact pads at an upper surface of the package-level substrate 602.

An underfill material 610 (e.g., capillary underfill) can be provided between the stack of semiconductor dies 502 and the package-level substrate 602 to provide electrical insulation to the interconnects 606 and structurally support the device. The stack of semiconductor dies 502 and the package-level substrate 602 can be at least partially encapsulated by an encapsulant material 612 (e.g., mold resin compound or the like) to prevent electrical contact therewith and provide mechanical strength and protection to the assembly.

Although in the foregoing example embodiment semiconductor device assemblies have been illustrated and described as including a particular configuration of semiconductor dies, in other embodiments, assemblies can be provided with different configurations of semiconductor dies. For example, the semiconductor device assemblies illustrated in any of the foregoing examples could be implemented with, for example, additional semiconductor dies in the stack of semiconductor dies, multiple stacks of semiconductor dies, mutatis mutandis. Any additional semiconductor dies or stacks of semiconductor dies could be coupled with other dies in the assembly through similar techniques as described for the stack of semiconductor dies 502, including the use of recessed portions within the passivation layer.

In accordance with one aspect of the present disclosure, the semiconductor devices illustrated in the assemblies of FIGS. 1-6 could be memory dies, such as dynamic random-access memory (DRAM) dies, NOT-AND (NAND) memory dies, NOT-OR (NOR) memory dies, magnetic random-access memory (MRAM) dies, phase change memory (PCM) dies, ferroelectric random-access memory (FeRAM) dies, SRAM dies, or the like. In an embodiment in which multiple dies are provided in a single assembly, the semiconductor devices could include memory dies of a same kind (e.g., both NAND, both DRAM, etc.) or memory dies of different kinds (e.g., one DRAM and one NAND, etc.). In accordance with another aspect of the present disclosure, the semiconductor dies of the assemblies illustrated and described above could be logic dies (e.g., controller dies, processor dies, etc.), or a mix of logic and memory dies (e.g., a memory controller die and a memory die controlled thereby).

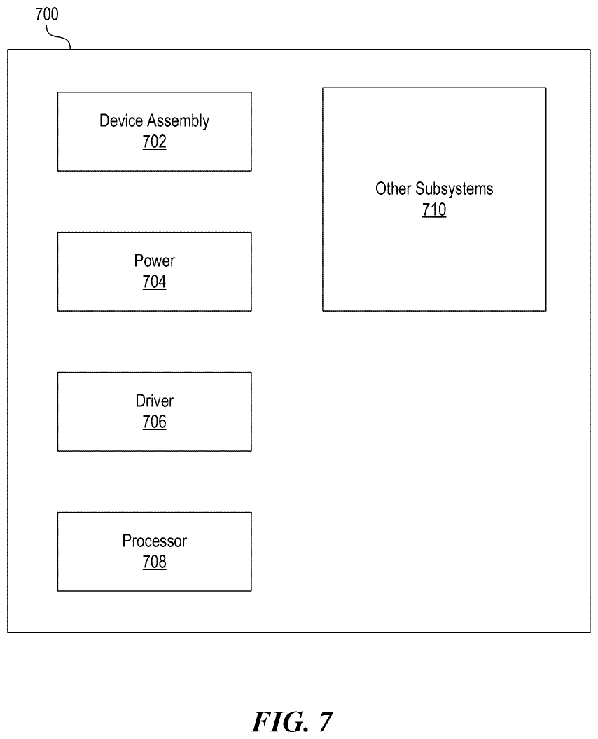

Any one of the semiconductor devices and semiconductor device assemblies described above with reference to FIGS. 1-6 can be incorporated into any of a myriad of larger and/or more complex systems, a representative example of which is system 700 shown schematically in FIG. 7. The system 700 can include a semiconductor device assembly 702 (e.g., a discrete semiconductor device), a power source 704, a driver 706, a processor 708, and/or other subsystems or components 710. The semiconductor device assembly 702 can include features generally similar to those of the semiconductor device assemblies described above with reference to FIGS. 1-6. The resulting system 700 can perform any of a wide variety of functions, such as memory storage, data processing, and/or other suitable functions. Accordingly, the representative system 700 can include, without limitation, hand-held devices (e.g., mobile phones, tablets, digital readers, and digital audio players), computers, vehicles, appliances, or other products. Components of the system 700 may be housed in a single unit or distributed over multiple, interconnected units (e.g., through a communications network). The components of the system 700 can also include remote devices and any of a wide variety of computer-readable media.

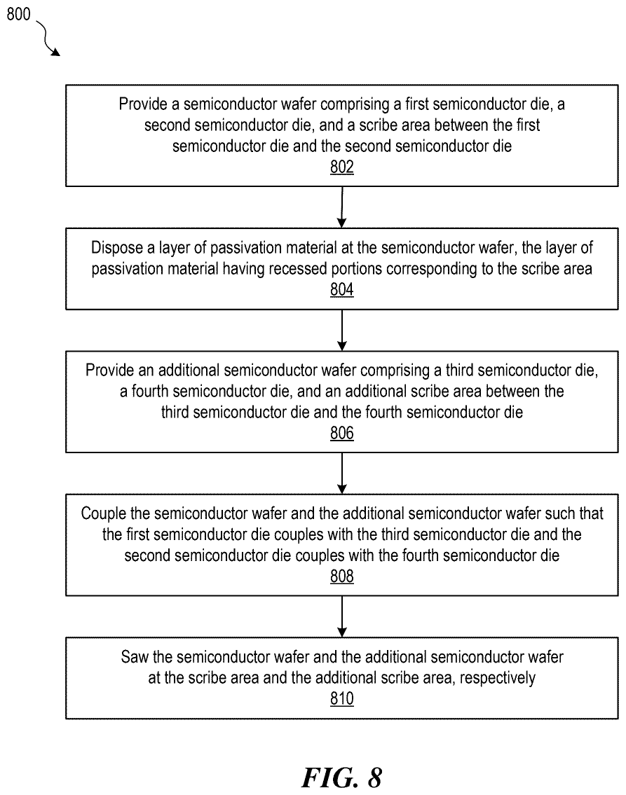

FIG. 8 illustrates a method 800 for assembling a semiconductor device in accordance with an embodiment of the present technology. Although illustrated in a particular configuration, one or more operations of the method 800 may be omitted, repeated, or reorganized. Additionally, the method 800 may include other operations not illustrated in FIG. 8, for example, operations detailed in one or more other methods described herein.

At 802, a semiconductor wafer is provided. The semiconductor wafer includes a first semiconductor die, a second semiconductor die, and a scribe area between the first semiconductor die and the second semiconductor die.

At 804, a layer of passivation material is disposed at the semiconductor wafer. The layer of passivation material includes recessed portions corresponding to the scribe area. The recessed portions can be implemented through various operations to deposit passivation material on the semiconductor wafer and remove passivation material from the semiconductor wafer. In general, the recessed portions are recessed from a bonding surface provided by the layer of passivation material. The passivation material can include an insulative material, such as a dielectric material (e.g., dielectric film), a polymer, or any other suitable material.

At 806, an additional semiconductor wafer is provided. The additional semiconductor wafer includes a third semiconductor die, a fourth semiconductor die, and an additional scribe area between the third semiconductor die and the fourth semiconductor die. The additional semiconductor wafer can have a similar layout to the semiconductor wafer. For example, the third semiconductor die can be located in a same lateral location as the first semiconductor die, the fourth semiconductor die can be located in a same lateral location as the second semiconductor die, and the additional scribe area can be located at a similar lateral location as the scribe area.

At 808, the semiconductor wafer and the additional semiconductor wafer are coupled. Coupling the wafers can couple the first semiconductor die with the third semiconductor die and the second semiconductor die with the fourth semiconductor die. Further, the scribe area and the additional scribe area can align when coupled. The wafers can be coupled through any appropriate bonding technique, for example, fusion or hybrid bonding. In some cases, moisture and other contaminants can be moved, formed, or released during the bonding process, and these contaminants can be trapped within the recessed portions to keep the bonding interface between the wafers free of the contaminants.

At 810, the semiconductor wafer and the additional semiconductor wafer can be sawed at the scribe area and the additional scribe area, respectively. Sawing the wafers can singulate individual stack of semiconductor dies that can be packaged into various electronic devices. In some cases, the wafers can be sawed at multiple locations within the scribe areas on opposite sides of the recessed portions. In doing so, the recessed portions, and the contaminants contained therein, can be absent from the singulated stacks of semiconductor dies. Thus, the techniques disclosed herein can improve reliability in wafer bonding processes with minimal changes to the resultant semiconductor devices.

Specific details of several embodiments of semiconductor devices, and associated systems and methods, are described above. Depending upon the context in which it is used, the term “substrate” can refer to a wafer-level substrate or to a singulated, die-level substrate. Furthermore, unless the context indicates otherwise, structures disclosed herein can be formed using conventional semiconductor-manufacturing techniques. Materials can be deposited, for example, using dispensing, CVD, PVD, atomic layer deposition, plating, electroless plating, spin coating, and/or other suitable techniques. Similarly, materials can be removed, for example, using plasma etching, wet etching, chemical-mechanical planarization (CMP), drilling, or other suitable techniques.

The technology disclosed herein relates to semiconductor devices, systems with semiconductor devices, and related methods for manufacturing semiconductor devices. The term “semiconductor device” generally refers to a solid-state device that includes one or more semiconductor materials. Examples of semiconductor devices include logic devices, memory devices, and diodes, among others. Furthermore, the term “semiconductor device” can refer to a finished device or to an assembly or other structure at various stages of processing before becoming a finished device. Depending upon the context in which it is used, the term “substrate” can refer to a structure that supports electronic components (e.g., a die), such as a PCB or wafer-level substrate, a die-level substrate, or another die for die-stacking or three-dimensional integration (3DI) applications.

The devices discussed herein, including a memory device, may be formed on a semiconductor substrate or die, such as silicon, germanium, silicon-germanium alloy, gallium arsenide, gallium nitride, etc. In some cases, the substrate is a semiconductor wafer. In other cases, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorus, boron, or arsenic. Doping may be performed during the initial formation or growth of the substrate, by ion-implantation, or by any other doping means.

The functions described herein may be implemented in hardware, software executed by a processor, firmware, or any combination thereof. Other examples and implementations are within the scope of the disclosure and appended claims. Features implementing functions may also be physically located at various positions, including being distributed such that portions of functions are implemented at different physical locations.

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, the terms “vertical,” “lateral,” “upper,” “lower,” “above,” and “below” can refer to relative directions or positions of features in the semiconductor devices in view of the orientation shown in the figures. For example, “upper” or “uppermost” can refer to a feature positioned closer to the top of a page than another feature. These terms, however, should be construed broadly to include semiconductor devices having other orientations, such as inverted or inclined orientations where top/bottom, over/under, above/below, up/down, and left/right can be interchanged depending on the orientation.

From the foregoing, it will be appreciated that specific embodiments of the invention have been described herein for purposes of illustration, but that various modifications may be made without deviating from the scope of the invention. Rather, in the foregoing description, numerous specific details are discussed to provide a thorough and enabling description for embodiments of the present technology. One skilled in the relevant art, however, will recognize that the disclosure can be practiced without one or more of the specific details. In other instances, well-known structures or operations often associated with memory systems and devices are not shown, or are not described in detail, to avoid obscuring other aspects of the technology. In general, it should be understood that various other devices, systems, and methods in addition to those specific embodiments disclosed herein may be within the scope of the present technology.

What is claimed is:

1. A semiconductor device assembly, comprising:
a semiconductor substrate on which a plurality of semiconductor dies are implemented, the semiconductor substrate having a scribe area between the plurality of semiconductor dies; and
a layer of passivation material disposed at a first side of the semiconductor substrate, the layer of passivation material comprising one or more recessed portions at the scribe area.

2. The semiconductor device assembly of claim 1, wherein:
the plurality of semiconductor dies comprises a first semiconductor die, a second semiconductor die, a third semiconductor die, and a fourth semiconductor die that are implemented on the semiconductor substrate; and
a first recessed portion of the one or more recessed portions is disposed between the first semiconductor die and the second semiconductor die and between the third semiconductor die and the fourth semiconductor die.

3. The semiconductor device assembly of claim 1, wherein:
the plurality of semiconductor dies comprises a first semiconductor die, a second semiconductor die, a third semiconductor die, and a fourth semiconductor die that are implemented on the semiconductor substrate;
a first discrete recessed portion of the one or more recessed portions is disposed between the first semiconductor die and the second semiconductor die; and
a second discrete recessed portion of the one or more recessed portions is disposed between the third semiconductor die and the fourth semiconductor die.

4. The semiconductor device assembly of claim 1, wherein:
the plurality of semiconductor dies comprises a first semiconductor die and a second semiconductor die; and
the one or more recessed portions comprise a plurality of discrete recessed portions disposed between the first semiconductor die and the second semiconductor die.

5. The semiconductor device assembly of claim 1, wherein the one or more recessed portions comprise a first recessed portion having a first major axis and a second recessed portion having a second major axis perpendicular to the first major axis.

6. The semiconductor device assembly of claim 1, wherein the one or more recessed portions comprise a first discrete recessed portion having a first major axis and a second discrete recessed portion having a second major axis parallel to the first major axis.

7. The semiconductor device assembly of claim 1, wherein the layer of passivation material comprises a dielectric material.

8. A method, comprising:
providing a semiconductor wafer comprising a first semiconductor die, a second semiconductor die, and a scribe area between the first semiconductor die and the second semiconductor die;
disposing a layer of passivation material at a first side of the semiconductor wafer, the layer of passivation material having one or more recessed portions corresponding to the scribe area;
providing an additional semiconductor wafer comprising a third semiconductor die, a fourth semiconductor die, and an additional scribe area between the third semiconductor die and the fourth semiconductor die;
coupling the semiconductor wafer and the additional semiconductor wafer at the first side such that the first semiconductor die couples with the third semiconductor die and the second semiconductor die couples with the fourth semiconductor die;
sawing the semiconductor wafer at the scribe area between the first semiconductor die and the second semiconductor die; and
sawing the additional semiconductor wafer at the additional scribe area between the third semiconductor die and the fourth semiconductor die.

9. The method of claim 8, further comprising:
sawing the semiconductor wafer at the scribe area between the first semiconductor die and the one or more recessed portions; and
sawing the semiconductor wafer at the scribe area between the second semiconductor die and the one or more recessed portions.

10. The method of claim 8, further comprising:
disposing an additional layer of passivation material at a second side of the additional semiconductor wafer, the additional layer of passivation material having one or more additional recessed portions corresponding to the additional scribe area; and
coupling the first side of the semiconductor wafer and the second side of the additional semiconductor wafer through the layer of passivation material and the additional layer of passivation material.

11. The method of claim 10, further comprising:
sawing the additional semiconductor wafer at the additional scribe area between the third semiconductor die and the one or more additional recessed portions; and
sawing the additional semiconductor wafer at the additional scribe area between the fourth semiconductor die and the one or more recessed portions.

12. The method of claim 8, further comprising:
disposing the layer of passivation material in a continuous layer; and
removing one or more portions of the passivation material to implement the one or more recessed portions.

13. The method of claim 8, further comprising coupling the semiconductor wafer and the additional semiconductor wafer through fusion bonding.

14. The method of claim 8, further comprising coupling the semiconductor wafer and the additional semiconductor wafer through hybrid bonding.

15. The method of claim 8, wherein:
the semiconductor wafer further comprises a fifth semiconductor die and a sixth semiconductor die;
the scribe area is between the fifth semiconductor die and the sixth semiconductor die; and
a first recessed portion of the one or more recessed portions is disposed between the first semiconductor die and the second semiconductor die and between the fifth semiconductor die and the sixth semiconductor die.

16. The method of claim 8, wherein the one or more recessed portions comprises a plurality of discrete recessed portions disposed between the first semiconductor die and the second semiconductor die.

17. A semiconductor wafer, comprising:
a first semiconductor die at a first lateral location of the semiconductor wafer;
a second semiconductor die at a second lateral location of the semiconductor wafer;
a scribe area separating the first semiconductor die and the second semiconductor die; and
a layer of passivation material disposed at a first side of the semiconductor wafer, the layer of passivation material having one or more recessed portions corresponding to the scribe area.

18. The semiconductor wafer of claim 17, further comprising:
a third semiconductor die at a third lateral location of the semiconductor wafer;
a fourth semiconductor die at a fourth lateral location of the semiconductor wafer, wherein the scribe area separates the third semiconductor die and the fourth semiconductor die; and
a first recessed portion of the one or more recessed portions disposed between the first semiconductor die and the second semiconductor die and between the third semiconductor die and the fourth semiconductor die.

19. The semiconductor wafer of claim 17, further comprising:
a third semiconductor die at a third lateral location of the semiconductor wafer;
a fourth semiconductor die at a fourth lateral location of the semiconductor wafer, wherein the scribe area separates the third semiconductor die and the fourth semiconductor die;
a first discrete recessed portion of the one or more recessed portions disposed between the first semiconductor die and the second semiconductor die; and
a second discrete recessed portion of the one or more recessed portions disposed between the third semiconductor die and the fourth semiconductor die.

20. The semiconductor wafer of claim 17, wherein the one or more recessed portions comprises a plurality of discrete recessed portions disposed between the first semiconductor die and the second semiconductor die.
